(19) United States
(12) Patent Application Publication
(10) Pub. No.: US 2025/0386640 A1
(43) Pub. Date: Dec. 18, 2025

(54) DISPLAY DEVICE, AND ELECTRONIC DEVICE INCLUDING THE SAME

(71) Applicant: Samsung Display Co., LTD., Yongin-si (KR)

(72) Inventors: Hye Jung HONG, Yongin-si (KR); Jae Ho CHOI, Yongin-si (KR); Joo Woan CHO, Yongin-si (KR)

(21) Appl. No.: 19/198,391

(22) Filed: May 5, 2025

(30) Foreign Application Priority Data
Jun. 18, 2024 (KR) 10-2024-0078775
Aug. 28, 2024 (KR) 10-2024-0116184

(51) Int. Cl. H10H 29/49; H01L 25/075

(52) U.S. Cl. CPC H10H 29/49; H01L 25/0753

(57) ABSTRACT

The display device includes a substrate including a first area and a second area not overlapping the first area; a plurality of light-emitting elements disposed on the substrate and which emit light; first transmission lines, which apply a first voltage to light-emitting elements overlapping with the first area among the plurality of light-emitting elements; second transmission lines insulated from the first transmission lines and which apply a second voltage to light-emitting elements overlapping with the second area among the plurality of light-emitting elements; and a connection layer connecting each of the first and second transmission lines with each of the plurality of light-emitting elements.

This application claims priority to Korean Patent Application No. 10-2024-0078775, filed on Jun. 18, 2024, and Korean Patent Application No. 10-2024-0116184, filed on Aug. 28, 2024, and all the benefits accruing therefrom under 35 U.S.C. § 119, the contents of which in their entirety are herein incorporated by reference.

### BACKGROUND

### 1. Field

The present invention relates to a display device and an electronic device including the same.

### 2. Description of the Related Art

Recently, with the increasing interest in information displays, research and development on display devices have been continuously conducted.

### SUMMARY

The problem to be solved by the present invention is to provide a display device with improved display quality.

The problems of the present invention are not limited to those mentioned above, and other technical problems not mentioned will be clearly understood by those skilled in the art from the description below.

A display device according to embodiments of the present invention includes a substrate including a first area and a second area not overlapping the first area; a plurality of light-emitting elements disposed on the substrate and for emitting light; first transmission lines for applying a first voltage to light-emitting elements overlapping with the first area among the plurality of light-emitting elements; second transmission lines insulated from the first transmission lines and for applying a second voltage to light-emitting elements overlapping with the second area among the plurality of light-emitting elements; and a connection layer connecting each of the first and second transmission lines to each of the plurality of light-emitting elements.

In one embodiment, the first area is located at the center of the substrate, and the second area may surround the first area.

In one embodiment, the first transmission lines are connected to each other and form a first mesh structure, and the second transmission lines are connected to each other and may form a second mesh structure.

In one embodiment, the display device may further include a first voltage terminal for receiving the first voltage and transmitting the first voltage to the first transmission lines; and a second voltage terminal for receiving the second voltage and transmitting the second voltage to the second transmission lines.

In one embodiment, the connection layer may include a plurality of connection electrodes spaced apart from each other.

In one embodiment, the plurality of connection electrodes may be electrically connected to the plurality of light-emitting elements, respectively.

In one embodiment, each of the plurality of connection electrodes may be electrically connected to one of the first transmission lines and the second transmission lines.

In one embodiment, the substrate may further include a third area not overlapping the first and second areas.

In one embodiment, the plurality of light-emitting elements may include first light-emitting elements for emitting light of a first color and overlapping with the first area; second light-emitting elements for emitting light of a second color different from the first color and overlapping with the second area; and third light-emitting elements for emitting light of a third color different from the first and second colors and overlapping with the third area.

In one embodiment, the display device may further include third transmission lines insulated from the first and second transmission lines and for applying a third voltage to the third light-emitting elements among the plurality of light-emitting elements.

In one embodiment, the first color may be red, the second color may be green, the third color may be blue, the third voltage may be greater than each of the first and second voltages, and the second voltage may be greater than the first voltage.

In one embodiment, each of the plurality of connection electrodes may be electrically connected to one of the first transmission lines, the second transmission lines, and the third transmission lines.

In one embodiment, the display device may further include a third voltage terminal for receiving the third voltage and transmitting the third voltage to the third transmission lines.

A display device according to embodiments of the present invention includes a substrate; a pixel circuit layer disposed on the substrate; a first insulating layer disposed on the pixel circuit layer; a first metal layer disposed on the first insulating layer and for receiving a first voltage; a second insulating layer disposed on the first metal layer; a second metal layer disposed on the second insulating layer and insulated from the first metal layer, and for receiving a second voltage separately applied from the first voltage; a third insulating layer disposed on the second metal layer; a connection layer disposed on the third insulating layer and electrically connected to each of the first metal layer and the second metal layer; and light-emitting elements disposed on the connection layer and electrically connected to the connection layer.

In one embodiment, the first metal layer may include first transmission lines connected to each other, and the second metal layer may include second transmission lines connected to each other.

In one embodiment, the connection layer may include a plurality of connection electrodes, which are spaced apart from each other and are each electrically connected to one of the first transmission lines and the second transmission lines.

In one embodiment, the first transmission lines may transmit the first voltage to some of the light-emitting elements through the connection electrodes, respectively, and the second transmission lines may transmit the second voltage to the remaining light-emitting elements among the light-emitting elements through the connection electrodes, respectively.

In one embodiment, the display device may further include anode electrodes disposed between the pixel circuit layer and the first insulating layer, and each of the anode electrodes may be electrically connected to one of the first transmission lines and the second transmission lines.

A display device according to embodiments of the present invention includes a substrate; a pixel circuit layer disposed on the substrate; light-emitting elements disposed on the pixel circuit layer; a connection layer disposed on the light-emitting elements and electrically connected to the light-emitting elements; a first insulating layer disposed on the connection layer; a first metal layer disposed on the first insulating layer electrically connected to the connection layer, and which receives a first voltage; a second insulating layer disposed on the first metal layer; and a second metal layer disposed on the second insulating layer, electrically connected to the connection layer, insulated from the first metal layer, and which receives a second voltage that is applied separately from the first voltage.

In one embodiment, the display device may further include cathode electrodes disposed on the second metal layer, and each of the cathode electrodes may be electrically connected to one of the first metal layer and the second metal layer.

An electronic device according to embodiments of the present invention includes a display device; and a power supply configured to provide power to the display device. The display device includes a substrate including a first area and a second area not overlapping the first area; a plurality of light-emitting elements disposed on the substrate and for emitting light; first transmission lines for applying a first voltage to light-emitting elements overlapping with the first area among the plurality of light-emitting elements; second transmission lines insulated from the first transmission lines and for applying a second voltage to light-emitting elements overlapping with the second area among the plurality of light-emitting elements; and a connection layer connecting each of the first and second transmission lines to each of the plurality of light-emitting elements.

Specific details of other embodiments are included in the detailed description and drawings.

According to the above-described embodiments, the transmission lines of the display panel are configured as multi-layer structures with two or more layers, allowing voltage to be individually supplied to each layer and applied to the light-emitting elements. That is, the first voltage or the second voltage may be individually applied to each of the first light-emitting elements and the second light-emitting elements. This allows separate voltages to be applied to different areas within the display area.

By designing separate voltages to be applied to different areas within the display area, the phenomenon of voltage drop (IR Drop) toward the central part of the display area can be mitigated, preventing luminance differences from occurring in different areas within the display area. Accordingly, the uniformity of the display panel by area is improved, and the display quality of the display panel can be effectively enhanced.

The effects according to the embodiments are not limited to the examples illustrated above, and various other effects are included within this specification.

### BRIEF DESCRIPTION OF THE DRAWINGS

FIG. 1 is a block diagram illustrating an embodiment of a display device.

FIG. 2 is a block diagram illustrating an embodiment of one of the sub-pixels in FIG. 1.

FIG. 3 is a plan view illustrating an embodiment of the display panel in FIG. 1.

FIG. 4 is a cross-sectional view illustrating an embodiment of the display panel in FIG. 3.

FIG. 5 is a cross-sectional view illustrating another embodiment of the display panel in FIG. 3.

FIG. 6 is a plan view schematically illustrating an embodiment of the display panel in FIG. 3.

FIG. 7 is a plan view schematically illustrating the connection layer in FIG. 6.

FIG. 8 is a plan view schematically illustrating the first metal layer in FIG. 6.

FIG. 9 is a plan view schematically illustrating the second metal layer in FIG. 6.

FIG. 10 is a cross-sectional view taken along lines I-I′ and II-II′ of FIG. 6.

FIG. 11 is a cross-sectional view illustrating another embodiment in FIG. 10.

FIG. 12 is a plan view schematically illustrating another embodiment of the display panel in FIG. 3.

FIG. 13 is a plan view schematically illustrating the connection layer FIG. 12.

FIG. 14 is a plan view schematically illustrating the first metal layer in FIG. 12.

FIG. 15 is a plan view schematically illustrating the second metal layer in FIG. 12.

FIG. 16 is a plan view schematically illustrating the third metal layer in FIG. 12.

FIG. 17 is a cross-sectional view taken along lines III-III′, IV-IV′, and V-V′ of FIG. 12.

FIG. 18 is a block diagram illustrating an embodiment of a display system.

FIGS. 19 to 22 are perspective views illustrating application examples of the display system in FIG. 18.

### DETAILED DESCRIPTION

The present invention may undergo various modifications and may have many forms. Specific embodiments are illustrated in the drawings and described in detail in the description. However, this is not intended to limit the invention to the particular disclosed forms, and it is to be understood that all modifications, equivalents, and substitutions that fall within the spirit and technical scope of the invention are encompassed within the present invention.

In describing each drawing, similar reference numerals have been used for similar components. In the attached drawings, the dimensions of the structures are enlarged than they actually are for clarity of the present invention. Terms such as “first”, “second”, and the like may be used to describe various components, but these components should not be limited by these terms. These terms are only used to distinguish one component from another. For example, without departing from the scope of the invention, a first component could be referred to as a second component, and similarly, a second component could be referred to as a first component.

In this application, terms such as “include” or “have” are intended to indicate the presence of features, numbers, steps, actions, components, parts, or combinations thereof described in the specification, and should be understood not to preclude the possibility of the presence or addition of one or more other features, numbers, steps, actions, components, parts, or combinations thereof. When a layer, film, area, or plate is said to be “on” another part, it includes not only the case where it is “directly on” top of that part, but also the case where another part is between them. In this specification, when a layer, film, area, or plate is said to be formed “on” another part, the direction in which it is formed is not limited to the upper direction and may include lateral or lower directions. Conversely, when a layer, film, area, or plate is said to be “below” another part, this includes not only the case where it is “directly below” the other part, but also the case where another part is between them.

Hereinafter, preferred embodiments of the present invention and other details necessary for those skilled in the art to easily understand the invention will be described in detail with reference to the accompanying drawings. In the following description, singular expressions include plural expressions unless the context clearly dictates otherwise.

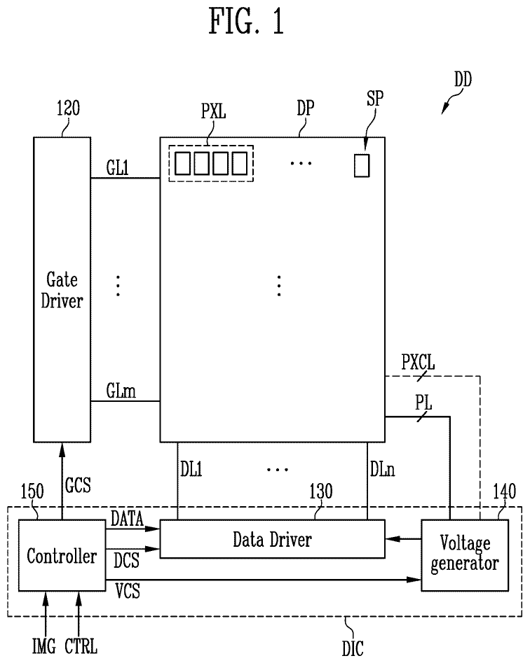

FIG. 1 is a block diagram illustrating an embodiment of a display device.

Referring to FIG. 1, the display device DD may include a display panel DP, a gate driver 120, a data driver 130, a voltage generator 140, and a controller 150. The voltage generator 140 may be referred to as a power supply.

The display panel DP includes sub-pixels SP. The sub-pixels SP may be connected to the gate driver 120 via the first to m-th gate lines GL1 to GLm. The sub-pixels SP may be connected to the data driver 130 via the first to n-th data lines DL1 to DLn.

The sub-pixels SP may generate light in two or more colors. For example, each of sub-pixels SP may generate light such as red, green, blue, cyan, magenta, yellow, and the like.

Two or more sub-pixels among the sub-pixels SP may form one pixel PXL. For example, as shown in FIG. 1, the pixel PXL may include four sub-pixels SP. In this way, the pixel PXL may emit light of various colors and various brightnesses based on the combination of light emitted from the sub-pixels SP included in it.

The gate driver 120 is connected to the sub-pixels SP arranged in the row direction via the first to m-th gate lines GL1 to GLm. The gate driver 120 may output gate signals to the first to m-th gate lines GL1 to GLm in response to the gate control signal GCS. In one embodiment, the gate control signal GCS may include a start signal indicating the beginning of each frame, a horizontal synchronization signal, and the like.

The gate driver 120 may be disposed on one side of the display panel DP. However, the embodiments are not limited to this. For example, the gate driver 120 may be divided into two or more drivers that are physically and/or logically separated, and such drivers may be disposed on one side of the display panel DP and on the other side of the display panel DP opposite the one side. In this way, the gate driver 120 may be arranged around the display panel DP in various forms depending on the embodiments.

The data driver 130 is connected to the sub-pixels SP arranged in the column direction via the first to n-th data lines DL1 to DLn. The data driver 130 receives image data DATA and a data control signal DCS from the controller 150. The data driver 130 operates in response to the data control signal DCS. In one embodiment, the data control signal DCS may include a source start signal, a source shift clock, a source output enable signal, and the like.

The data driver 130 may receive voltages from the voltage generator 140. The data driver 130 may apply data signals, which have gradation voltages corresponding to the image data DATA, to the first to n-th data lines DL1 to DLn using the received voltages. When gate signals are applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display an image.

In one embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to components of the display device DD, such as the gate driver 120, the data driver 130, and the controller 150. The voltage generator 140 may receive input voltage from outside the display device DD and regulate the received voltage to generate a plurality of voltages.

The voltage generator 140 may generate a first power voltage and a second power voltage. The generated first and second power voltages may be provided to the sub-pixels SP via the power lines PL. In other embodiments, at least one of the first and second power voltages may be provided from outside the display device DD.

In addition, the voltage generator 140 may provide various voltages and/or signals. For example, the voltage generator 140 may provide one or more initialization voltages applied to the sub-pixels SP. For instance, during a sensing operation for sensing the electrical characteristics of transistors and/or light-emitting elements of the sub-pixels SP, a predetermined reference voltage may be applied to the first to n-th data lines DL1 to DLn, and the voltage generator 140 may generate the reference voltage and transmit it to the data driver 130. For example, during a display operation for displaying an image on the display panel DP, common pixel control signals may be applied to the sub-pixels SP, and the voltage generator 140 may generate those pixel control signals. In one embodiment, the voltage generator 140 may provide the pixel control signals to the sub-pixels SP via the pixel control lines PXCL. In FIG. 1, the pixel control lines PXCL are shown as being connected between the voltage generator 140 and the display panel DP, but the embodiments are not limited thereto. For example, the pixel control lines PXCL may be connected between the gate driver 120 and the display panel DP. In such cases, the pixel control signals may be transmitted from the voltage generator 140 to the pixel control lines PXCL via the gate driver 120.

The controller 150 controls the overall operations of the display device DD. The controller 150 receives input image data IMG and corresponding control signals CTRL from outside. The controller 150, in response to the control signals CTRL, may provide the gate control signals GCS, data control signals DCS, and voltage control signals VCS.

The controller 150 may convert the input image data IMG to be suitable for the display device DD or the display panel DP and output the image data DATA. In one embodiment, the controller 150 may arrange the input image data IMG to be suitable for the sub-pixels SP on a row-by-row basis and output the image data DATA.

Two or more of the components, such as the data driver 130, the voltage generator 140, and the controller 150, may be mounted on a single integrated circuit. As shown in FIG. 1, the data driver 130, the voltage generator 140, and the controller 150 may be included in the driver integrated circuit DIC. In such cases, the data driver 130, the voltage generator 140, and the controller 150 may be functionally separated components within a single driver integrated circuit DIC. In other embodiments, at least one of the data drivers 130, the voltage generator 140, and the controller 150 may be provided as a separate component from the driver integrated circuit DIC.

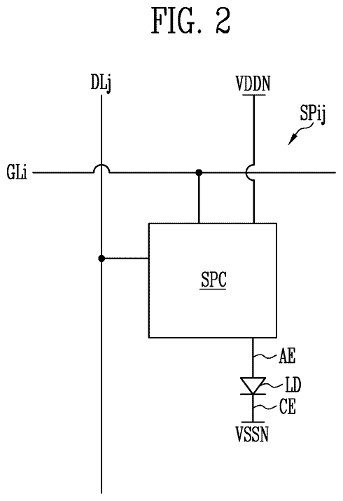

FIG. 2 is a block diagram showing one embodiment of the sub-pixels SP in FIG. 1. In FIG. 2, sub-pixel SPij of the subpixels SP of FIG. 1, arranged at row i (where i is an integer greater than or equal to 1 and less than or equal to m) and column j (where j is an integer greater than or equal to 1 and less than or equal to n), is exemplarily illustrated.

Referring to FIG. 2, the sub-pixel SPij may include a sub-pixel circuit SPC and a light-emitting element LD.

The light-emitting element LD is connected between the first power voltage node VDDN and the second power voltage node VSSN. The first power voltage node VDDN is connected to one of the power lines PL of FIG. 1 to receive the first power voltage. The second power voltage node VSSN is connected to another one of the power lines PL of FIG. 1 to receive the second power voltage. The first power voltage may have a higher voltage level than the second power voltage.

The light-emitting element LD is connected between the anode electrode AE and the cathode electrode CE. The anode electrode AE may be connected to the first power voltage node VDDN via the sub-pixel circuit SPC. For example, the anode electrode AE may be connected to the first power voltage node VDDN via one or more transistors included in the sub-pixel circuit SPC. The cathode electrode CE may be connected to the second power voltage node VSSN. The light-emitting element LD is configured to emit light according to the current flowing from the anode electrode AE to the cathode electrode CE.

The sub-pixel circuit SPC may be connected to the i-th gate line GLi among the first to m-th gate lines GL1 to GLm of FIG. 1 and the j-th data line DLj among the first to n-th data lines DL1 to DLn of FIG. 1. In response to a gate signal received via the i-th gate line GLi, the sub-pixel circuit SPC controls the light-emitting element LD to emit light according to the data signal received via the j-th data line DLj. In one embodiment, the sub-pixel circuit SPC may also be connected to the pixel control lines PXCL of FIG. 1. In such cases, the sub-pixel circuit SPC may further control the light-emitting element LD in response to pixel control signals received via the pixel control lines PXCL.

To perform these operations, the sub-pixel circuit SPC may include pixel circuits, such as transistors and one or more capacitors.

The transistors of the sub-pixel circuit SPC may include P-type transistors and/or N-type transistors. In one embodiment, the transistors of the sub-pixel circuit SPC may include metal oxide silicon field effect transistors (MOSFETs). In one embodiment, the transistors of the sub-pixel circuit SPC may include amorphous silicon semiconductors, monocrystalline silicon semiconductors, polycrystalline silicon semiconductors, oxide semiconductors, or the like.

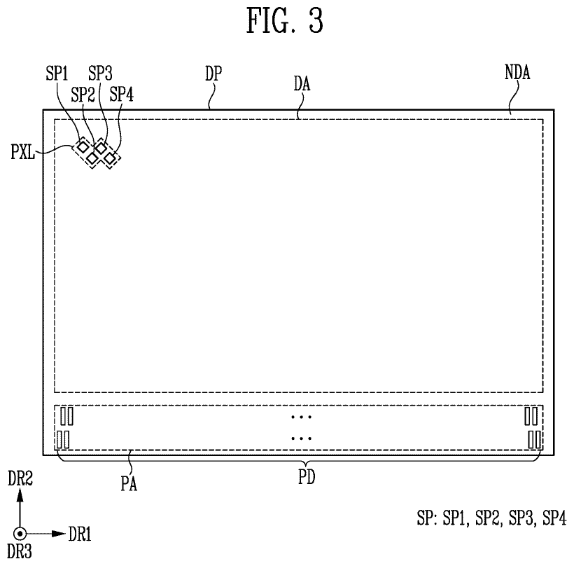

FIG. 3 is a plan view showing an embodiment of the display panel of FIG. 1.

Referring to FIG. 3, the display panel DP may include a display area DA, a non-display area NDA, and a pad area PA. The display panel DP displays an image through the display area DA. The pad area PA is spaced apart from the display area DA in the second direction DR2. The non-display area NDA is arranged around the display area DA.

The display panel DP includes sub-pixels SP in the display area DA. The sub-pixels SP may be arranged along the first direction DR1 and the second direction DR2 intersecting the first direction DR1. For example, the sub-pixels SP may be arranged in a zigzag pattern along the first direction DR1 and the second direction DR2. In another example, the sub-pixels SP may be arranged in a matrix pattern along the first direction DR1 and the second direction DR2. The arrangement of the sub-pixels SP may vary depending on the embodiments. The first direction DR1 may be the row direction, and the second direction DR2 may be the column direction.

Two or more of the plurality of sub-pixels SP may form one pixel PXL. In FIG. 3, the pixel PXL is illustrated as including four sub-pixels SP1 to SP4, but the embodiments are not limited to this. For example, the pixel PXL may include two or three sub-pixels. For convenience of explanation, it is assumed that the pixel PXL includes the first to fourth sub-pixels SP1 to SP4.

Each of the first to fourth sub-pixels SP1 to SP4 may generate light in one of various colors such as red, green, blue, cyan, magenta, or yellow. For clarity and simplicity of explanation, it is assumed that the first sub-pixel SP1 is configured to generate red light, the second sub-pixel SP2 and the fourth sub-pixel SP4 are configured to generate green light, and the third sub-pixel SP3 is configured to generate blue light.

Each of the first to fourth sub-pixels SP1 to SP4 may include at least one light-emitting element configured to generate light. In one embodiment, the light-emitting elements of the first to fourth sub-pixels SP1 to SP4 may generate light of the same color. For example, the light-emitting elements of the first to fourth sub-pixels SP1 to SP4 may generate blue light. In another embodiment, the light-emitting elements of the first to fourth sub-pixels SP1 to SP4 may generate light in different colors. For example, the light-emitting elements of the first to fourth sub-pixels SP1 to SP4 may generate red-colored, green-colored, blue-colored, and green-colored light, respectively.

As the display panel DP, a self-emissive display panel such as an LED display panel using micro-scale or nano-scale light-emitting diodes as light-emitting elements or an organic light-emitting display panel (OLED panel) using organic light-emitting diodes as light-emitting elements may be used.

In the non-display area NDA, components for controlling the sub-pixels SP and transmitting signals from the pads PD may be arranged. In the non-display area NDA, pads PD for supplying the first power voltage VDDN and the second power voltage VSSN of FIG. 2 to the power lines PL of FIG. 1, and signal lines connected to the first to m-th gate lines GL1 to GLm and the first to n-th data lines DL1 to DLn of FIG. 1, respectively, may be arranged.

The cathode electrode CE of FIG. 2 may receive the second power voltage VSSN from some of the pads PD and supply the second power voltage VSSN to the N-type semiconductor layer side of the light-emitting element, while other parts of pads PD, excluding those supplying the second power voltage VSSN, may supply the first power voltage VDDN to the P-type semiconductor layer side of the light-emitting element through the anode electrode AE. The light-emitting element may emit light due to the voltage difference between the first power voltage VDDN and the second power voltage VSSN.

At least one of the gate drivers 120, data driver 130, voltage generator 140, and controller 150 of FIG. 1 may be arranged in the non-display area NDA of the display panel DP. In one embodiment, the gate driver 120 may be arranged in the non-display area NDA. In such a case, the data driver 130, voltage generator 140, and controller 150 may be implemented as the driver integrated circuit DIC of FIG. 1, separate from the display panel DP, and the driver integrated circuit DIC may be connected to the wirings arranged in the non-display area NDA via the pads PD. In another embodiment, the gate driver 120 may be implemented as a single integrated circuit separate from the display panel DP along with the data driver 130, voltage generator 140, and controller 150.

In the pad area PA, pads PD that are connected to the wirings arranged in the non-display area NDA, respectively, may be arranged. The pads PD may be connected to the driver integrated circuit DIC.

In one embodiment, the display area DA may have various shapes. The display area DA may have the shape of a closed loop including straight and/or curved edges. For example, the display area DA may have shapes such as a polygon, circle, semicircle, or ellipse.

In one embodiment, the display panel DP may have a flat display surface. In another embodiment, the display panel DP may have at least a partially curved display surface. In one embodiment, the display panel DP may be bendable, foldable, or rollable. In such cases, the display panel DP and/or the substrate of the display panel DP may include flexible materials.

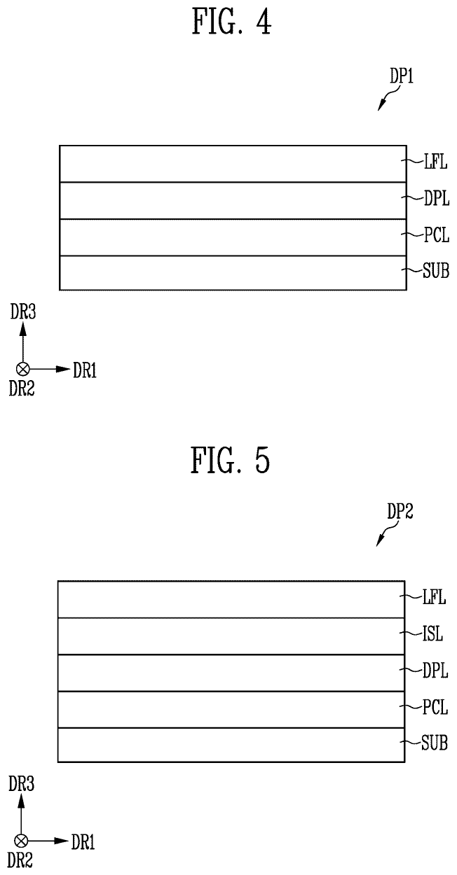

FIG. 4 is a cross-sectional view showing an embodiment of the display panel of FIG. 3.

Referring to FIG. 4, the display panel DP1 may include a substrate SUB, and on the substrate SUB, a pixel circuit layer PCL, a display element layer DPL, and a light functional layer LFL sequentially stacked in the third direction DR3, which intersects the first and second directions DR1 and DR2.

The substrate SUB may be made of an insulating material such as glass or resin. For example, the substrate SUB may include a glass substrate. In another example, the substrate SUB may include a polyimide (PI) substrate. In yet another example, the substrate SUB may include a silicon wafer substrate formed by a semiconductor process.

In one embodiment, the substrate SUB may be made of a flexible material that allows it to bend or fold, and may have a single-layer or multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate. However, embodiments are not limited to these materials.

A pixel circuit layer PCL is arranged on the substrate SUB. The pixel circuit layer PCL may include insulating layers and semiconductor electrodes and conductive electrodes arranged between the insulating layers. The conductive electrodes of the pixel circuit layer PCL may function as circuit elements, wirings, etc.

The circuit elements of the pixel circuit layer PCL may include sub-pixel circuits SPC (see FIG. 2) of each sub-pixel SP in FIG. 3. In other words, the circuit elements of the pixel circuit layer PCL may be provided by the transistors and one or more capacitors of the sub-pixel circuits SPC.

The wirings of the pixel circuit layer PCL may include wirings connected to the sub-pixels SP. The wirings of the pixel circuit layer PCL may include various signal lines and/or power lines for driving the display element layer DPL.

A display element layer DPL is arranged on the pixel circuit layer PCL. The display element layer DPL may include the light-emitting elements of the sub-pixels SP.

A light functional layer LFL may be arranged on the display element layer DPL. The light functional layer LFL may include light conversion patterns having color conversion particles and/or scattering particles. For example, the color conversion particles may include quantum dots. Quantum dots may change the wavelength (or color) of light emitted from the display element layer DPL. The light functional layer LFL may further include light scattering patterns having scattering particles. In one embodiment, the light conversion patterns and light scattering patterns may be omitted.

The light functional layer LFL may further include a color filter layer including color filters. The color filters may selectively transmit light of specific wavelengths (or specific colors). In one embodiment, the color filter layer may be omitted.

A window may be provided on the light functional layer LFL to protect the exposed surface (or upper surface) of the display panel DP1. The window may protect the display panel DP1 from external impacts. The window may be bonded to the light functional layer LFL via an optically transparent adhesive (or bonding) member. The window may have a multi-layer structure selected from a glass substrate, a plastic film, or a plastic substrate. This multi-layer structure may be formed through a continuous process or a bonding process using an adhesive layer. All or part of the window may be flexible.

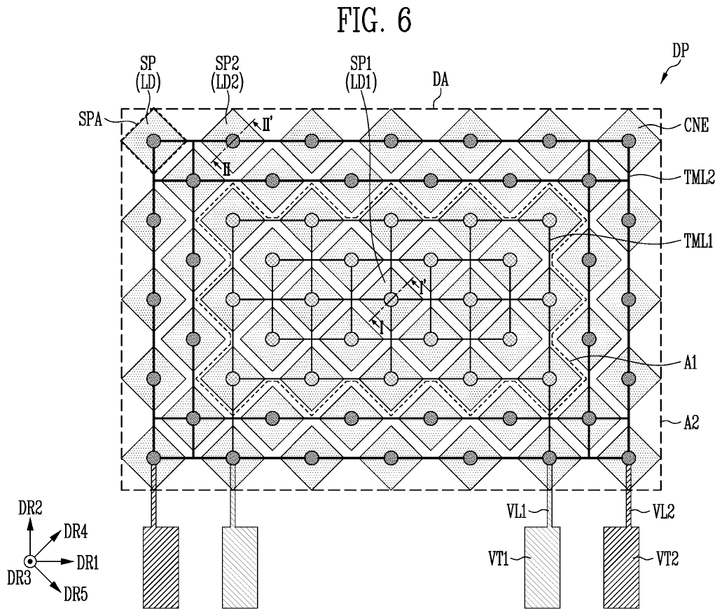

FIG. 5 is a cross-sectional view showing another embodiment of the display panel of FIG. 3.

Referring to FIG. 5, the display panel DP2 may include a substrate SUB, a pixel circuit layer PCL, a display element layer DPL, an input sensing layer ISL, and a light functional layer LFL. The substrate SUB, pixel circuit layer PCL, display element layer DPL, and light functional layer LFL are configured similarly to the substrate SUB, pixel circuit layer PCL, display element layer DPL, and light functional layer LFL described with reference to FIG. 4, respectively. The redundant explanations are omitted hereafter.

The input sensing layer ISL may detect user inputs on the upper surface (or display surface) of the display panel DP2. The input sensing layer ISL may include configurations suitable for detecting external objects such as a user's hand or a pen. For example, the input sensing layer ISL may include touch electrodes.

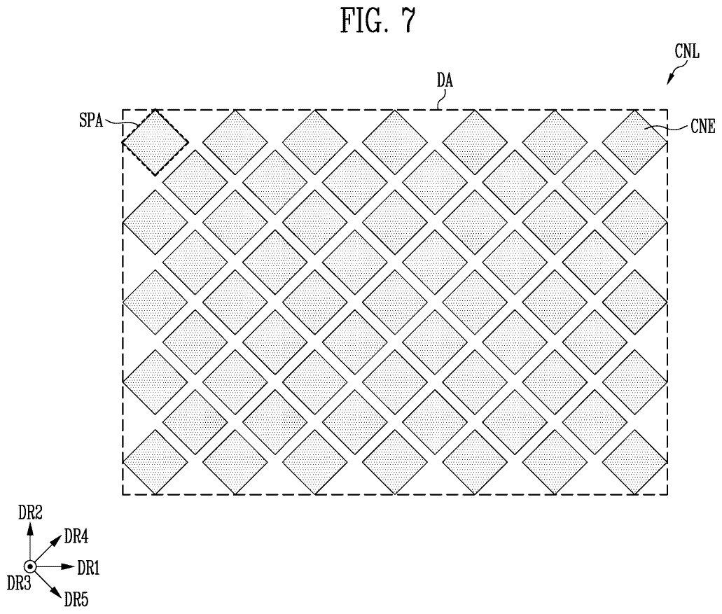

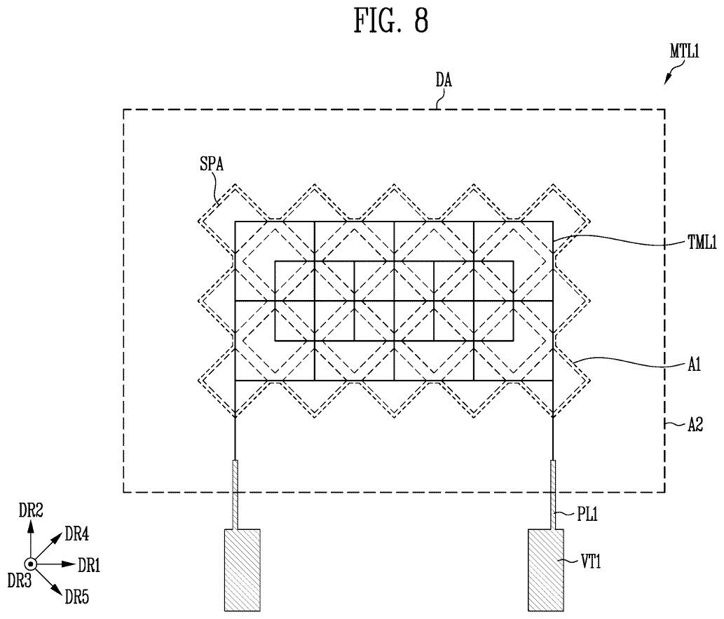

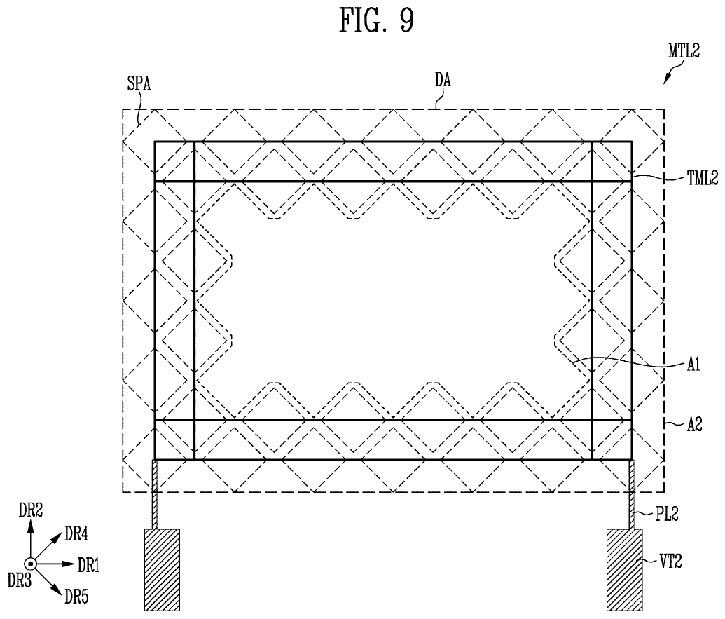

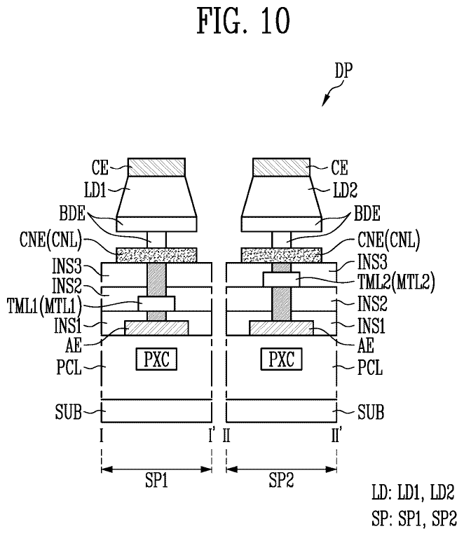

FIG. 6 is a plan view schematically showing an embodiment of the display panel of FIG. 3. FIG. 7 is a plan view schematically showing the connection layer of FIG. 6. FIG. 8 is a plan view schematically showing the first metal layer of FIG. 6. FIG. 9 is a plan view schematically showing the second metal layer of FIG. 6.

Referring to FIG. 6, sub-pixels SP are included in the display area DA. In one embodiment, the sub-pixels SP may be arranged in a zigzag Pentile™ structure along the fourth direction DR4 between the first direction DR1 and the second direction DR2, and the fifth direction DR5 orthogonal to the fourth direction DR4. The sub-pixels SP may be arranged in sub-pixel areas SPA, respectively.

In the display panel DP, the display area DA may include a first area A1 and a second area A2. The first area A1 may be located in the center of the display area DA of the substrate SUB. The second area A2 is the area of the display area DA excluding the first area A1 and may be located at the outer portion of the display area DA. In this case, the second area A2 may surround the first area A1. However, the embodiments are not limited to this, and the arrangement of the first and second areas A1 and A2 in the display area DA is not limited thereto. Furthermore, the display area DA may be divided into three or more areas.

The sub-pixels SP may each include light-emitting elements LD that generate and emit light. In other words, light-emitting elements LD may be arranged in sub-pixel areas SPA, respectively. The light-emitting elements LD may include first light-emitting elements LD1 overlapping with the first area A1 and second light-emitting elements LD2 overlapping with the second area A2.

Referring further to FIG. 7, the display panel DP may include a connection layer CNL. The connection layer CNL may include connection electrodes CNE arranged in sub-pixel areas SPA, respectively. The connection electrodes CNE may be spaced apart from each other and may be electrically connected to the light-emitting elements LD, respectively. That is, one connection electrode CNE may correspond to one sub-pixel SP. Each of the connection electrodes CNE may be electrically connected to one of the first transmission lines TML1 and the second transmission lines TML2, which will be described later.

Referring further to FIG. 8, the display panel DP may include a first metal layer MTL1. The first metal layer MTL1 may include first transmission lines TML1 arranged in the first area A1. The first transmission lines TML1 may be electrically connected to the first light-emitting elements LD1 overlapping with the first area A1. The first transmission lines TML1 may apply a first voltage to the first light-emitting elements LD1.

The first transmission lines TML1 may be electrically connected to the connection electrodes CNE arranged in the first area A1. The first transmission lines TML1 may be electrically connected to the light-emitting elements LD through the connection electrodes CNE arranged in the first area A1. That is, the connection electrodes CNE overlapping with the first area A1 may connect the first transmission lines TML1 and the first light-emitting elements LD1.

To overall apply the first voltage to the first light-emitting elements LD1 overlapping with the first area A1, the first transmission lines TML1 may be interconnected to form a mesh structure.

The display panel DP may further include a first voltage terminal VT1. The first voltage terminal VT1 may be arranged in the pad area PA. The first voltage terminal VT1 may receive the first voltage and deliver it to the first transmission lines TML1. The first power line PL1 may be connected to the first voltage terminal VT1 and each of the first transmission lines TML1, and may transmit the first voltage from the first voltage terminal VT1 to the first transmission lines TML1.

Referring further to FIG. 9, the display panel DP may include a second metal layer MTL2. The second metal layer MTL2 may include second transmission lines TML2 arranged in the second area A2. The second transmission lines TML2 may be electrically connected to the second light-emitting elements LD2 overlapping with the second area A2. The second transmission lines TML2 may apply a second voltage to the second light-emitting elements LD2. In this case, the second voltage may be less than or equal to the first voltage.

The second transmission lines TML2 may be electrically connected to the connection electrodes CNE arranged in the second area A2. The second transmission lines TML2 may be electrically connected to the light-emitting elements LD through the connection electrodes CNE arranged in the second area A2. That is, the connection electrodes CNE overlapping with the second area A2 may connect the second transmission lines TML2 and the second light-emitting elements LD2.

To overall apply the second voltage to the second light-emitting elements LD2 overlapping with the second area A2, the second transmission lines TML2 may be interconnected to form a mesh structure.

The second transmission lines TML2 are insulated from the first transmission lines TML1, so the second voltage may be applied to the second light-emitting elements LD2 separately from the first voltage applied to the first light-emitting elements LD1. In addition, since the first area A1 and the second area A2 are separated from each other, the first transmission lines TML1 and the second transmission lines TML2 may not overlap each other on the same plane.

The display panel DP may further include a second voltage terminal VT2. The second voltage terminal VT2 may be disposed in the pad area PA. The second voltage terminal VT2 may receive the second voltage and transmit the second voltage to the second transmission lines TML2. The second power line PL2 may be connected to each of the second voltage terminal VT2 and each of the second transmission lines TML2, and transmit the second voltage from the second voltage terminal VT2 to the second transmission lines TML2.

The first voltage may be transmitted only to the first light-emitting elements LD1 through the first transmission lines TML1 from the first voltage terminal VT1, and the second voltage may be transmitted only to the second light-emitting elements LD2 through the second transmission lines TML2 from the second voltage terminal VT2. That is, since the transmission lines TML1, TML2 of the display panel DP are formed as a multi-layer structure with two or more layers, the voltage may be applied to the light-emitting elements, with each layer for receiving a separate voltage. As a result, the first voltage or the second voltage may be applied individually to the first light-emitting elements LD1 and the second light-emitting elements LD2, respectively. This allows separate voltages to be applied to different areas within the display area DA.

In one embodiment, by designing the display area DA to apply separate voltages to different areas, the phenomenon of voltage drop (IR drop) toward the center of the display area DA may be alleviated. When separate voltages are applied to different areas within the display area DA, the resistance may be distributed across the areas, which may mitigate the voltage drop caused by the resistance. Therefore, the voltage difference applied to both ends of the light-emitting elements LD in the entire display area DA may not be significant. Accordingly, the voltage difference applied to both ends of the light-emitting element LD in the entire display area DA may be located in the saturation area (where the current does not change even if the voltage changes) in the current graph according to the voltage difference, and the current flowing according to the voltage difference may be output as preset in the entire display area DA. Since the current is output uniformly across the entire display area DA, the occurrence of luminance differences between areas in the display area DA may be prevented. Accordingly, the uniformity across the areas of the display panel DP may be improved, and the display quality of the display panel DP may be enhanced.

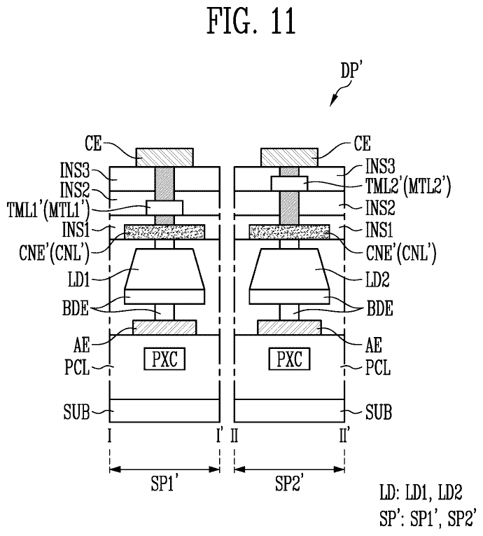

FIG. 10 is a cross-sectional view taken along lines I-I′ and II-II′ of FIG. 6.

Referring to FIG. 10, a pixel circuit layer PCL may be disposed on the substrate SUB. The pixel circuit layer PCL may include circuit elements PXC corresponding to the sub-pixels SP, respectively.

Anode electrodes AE may be disposed on the pixel circuit layer PCL. The anode electrodes AE may each be included in the sub-pixels SP and may be connected to the corresponding circuit elements PXC, respectively.

Each anode electrode AE may be electrically connected to one of the first transmission lines TML1 and the second transmission lines TML2. Through the first transmission lines TML1 or the second transmission lines TML2, each anode electrode AE may receive the first voltage or the second voltage.

A first insulating layer INS1 may be disposed on the pixel circuit layer PCL. The first insulating layer INS1 may cover the anode electrodes AE on the anode electrodes AE. A first metal layer MTL1 may be disposed on the first insulating layer INS1. The first metal layer MTL1 includes the first transmission line TML1 and may receive the first voltage. The first transmission line TML1 may overlap with the first sub-pixel SP1 and may be electrically connected to the anode electrode AE included in the first sub-pixel SP1 through a contact hole penetrating the first insulating layer INS1. That is, the first transmission lines TML1 may each transmit the first voltage to some of the light-emitting elements LD, for example, the first light-emitting elements LD1, through the connection electrodes CNE.

A second insulating layer INS2 may be disposed on the first insulating layer INS1. The second insulating layer INS2 may cover the first metal layer MTL1 on the first metal layer MTL1.

A second metal layer MTL2 may be disposed on the second insulating layer INS2. The second metal layer MTL2 may be insulated from the first metal layer MTL1. The second metal layer MTL2 includes the second transmission line TML2 and may receive the second voltage, which is applied separately from the first voltage. The second transmission line TML2 may overlap with the second sub-pixel SP2 and may be electrically connected to the anode electrode AE included in the second sub-pixel SP2 through a contact hole penetrating both the first insulating layer INS1 and the second insulating layer INS2. That is, the second transmission lines TML2 may each transmit the second voltage to the remaining light-emitting elements among the light-emitting elements LD, for example, the second light-emitting element LD2, through the connection electrodes CNE.

Although FIG. 10 describes the second metal layer MTL2 as being disposed on the first metal layer MTL1, this is exemplary, and in other embodiments, the stacking order of the first metal layer MTL1 and the second metal layer MTL2 may vary.

A third insulating layer INS3 may be disposed on the second insulating layer INS2. The third insulating layer INS3 may cover the second metal layer MTL2 on the second metal layer MTL2.

A connection layer CNL may be disposed on the third insulating layer INS3. The connection layer CNL may be separately connected to each of the first metal layer MTL1 and the second metal layer MTL2. Specifically, the connection layer CNL may include connection electrodes CNE that are spaced apart from each other. The connection electrodes CNE may overlap with the sub-pixels SP, respectively. Each of the connection electrodes CNE may be electrically connected to one of the first transmission line TML1 or the second transmission line TML2.

Bonding electrodes BDE may be disposed on the connection layer CNL. Light-emitting elements LD may be disposed on the bonding electrodes BDE. The light-emitting elements LD may each be included in the sub-pixels SP and may each be electrically connected to the connection electrodes CNE of the connection layer CNL through the bonding electrodes BDE. Specifically, the first light-emitting element LD1 may be included in the first sub-pixel SP1, and the second light-emitting element LD2 may be included in the second sub-pixel SP2.

Cathode electrodes CE may be disposed on the light-emitting elements LD, respectively. The cathode electrodes CE may be directly connected to the light-emitting elements LD. In this case, the cathode electrodes CE may be electrically connected to each other as a common electrode.

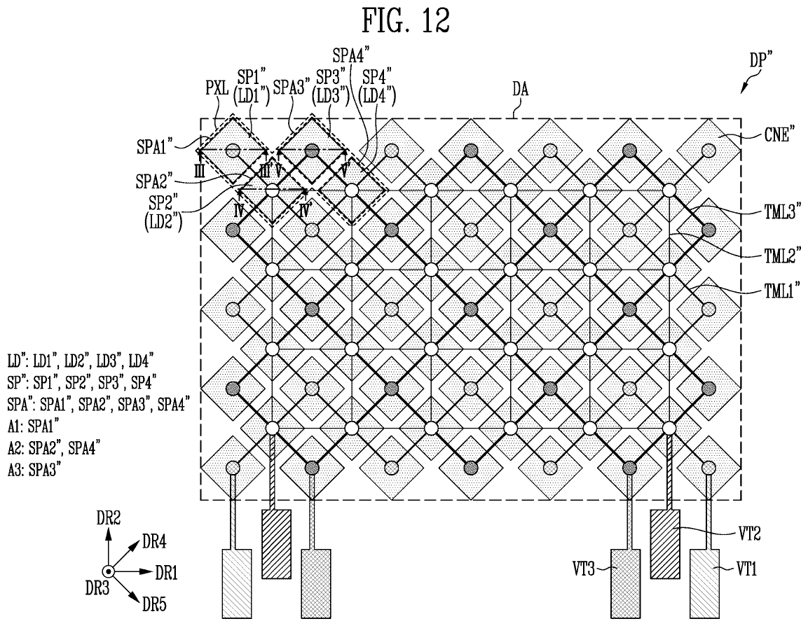

FIG. 11 is a cross-sectional view showing another embodiment of FIG. 10.

Referring to FIG. 11, a pixel circuit layer PCL may be disposed on the substrate SUB. Anode electrodes AE may be disposed on the pixel circuit layer PCL. The anode electrodes AE may each be included in the sub-pixels SP′ and may each be connected to the corresponding circuit elements PXC.

Bonding electrodes BDE may be disposed on the anode electrodes AE, respectively. Light-emitting elements LD may be disposed on the bonding electrodes BDE. The light-emitting elements LD may each overlap with the sub-pixels SP′ and may each be electrically connected to the anode electrodes AE through the bonding electrodes BDE. In this case, the anode electrodes AE may be electrically connected to each other as a common electrode.

A connection layer CNL′ may be disposed on the light-emitting elements LD. The connection layer CNL′ includes connection electrodes CNE′, and the connection electrodes CNE′ may be electrically connected to the light-emitting elements LD, respectively.

A first insulating layer INS1 may be disposed on the connection layer CNL′. The first insulating layer INS1 may cover the connection layer CNL′ on the connection layer CNL′.

A first metal layer MTL1′ may be disposed on the first insulating layer INS1. The first metal layer MTL1′ includes a first transmission line TML1′ and may receive a first voltage. The first transmission line TML1′ overlaps with the first sub-pixel SP1′ and may be electrically connected to the connection electrode CNE′ of the connection layer CNL′ overlapping with the first sub-pixel SP1′ through a contact hole penetrating the first insulating layer INS1. That is, the first transmission lines TML1′ may each transmit the first voltage to some of the light-emitting elements LD, for example, the first light-emitting elements LD1, through the connection electrodes CNE′.

A second insulating layer INS2 may be disposed on the first insulating layer INS1. The second insulating layer INS2 may cover the first metal layer MTL1′ on the first metal layer MTL1′.

A second metal layer MTL2′ may be disposed on the second insulating layer INS2. The second metal layer MTL2′ may be insulated from the first metal layer MTL1′. The second metal layer MTL2′ includes a second transmission line TML2′ and may receive a second voltage that is applied separately from the first voltage. The second transmission line TML2′ overlaps with the second sub-pixel SP2′ and may be electrically connected to the connection electrode CNE′ of the connection layer CNL′ overlapping with the second sub-pixel SP2′ through a contact hole penetrating the first insulating layer INS1 and the second insulating layer INS2. That is, the second transmission lines TML2′ may each transmit the second voltage to the remaining light-emitting elements among the light-emitting elements LD, for example, the second light-emitting elements LD2, through the connection electrodes CNE′.

Although in FIG. 11, the second metal layer MTL2′ is described as being disposed on the first metal layer MTL1′, this is merely illustrative, and in the embodiments, the stacking order of the first metal layer MTL1′ and the second metal layer MTL2′ may vary.

A third insulating layer INS3 may be disposed on the second insulating layer INS2. The third insulating layer INS3 may cover the second metal layer MTL2′ on the second metal layer MTL2′.

Cathode electrodes CE may be disposed on the third insulating layer INS3. Each of the cathode electrodes CE may be electrically connected to one of either the first metal layer MTL1′ or the second metal layer MTL2′. For example, the cathode electrode CE included in the first sub-pixel SP1′ may be electrically connected to the first transmission line TML1′ of the first metal layer MTL1′, and the cathode electrode CE included in the second sub-pixel SP2′ may be electrically connected to the second transmission line TML2′ of the second metal layer MTL2′. Through the first transmission lines TML1′ or the second transmission lines TML2′, each of the cathode electrodes CE may receive the first voltage or the second voltage.

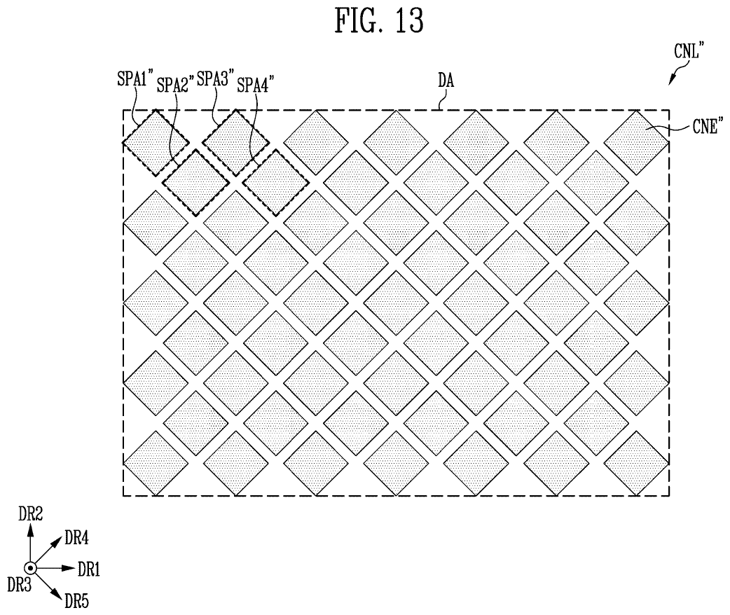

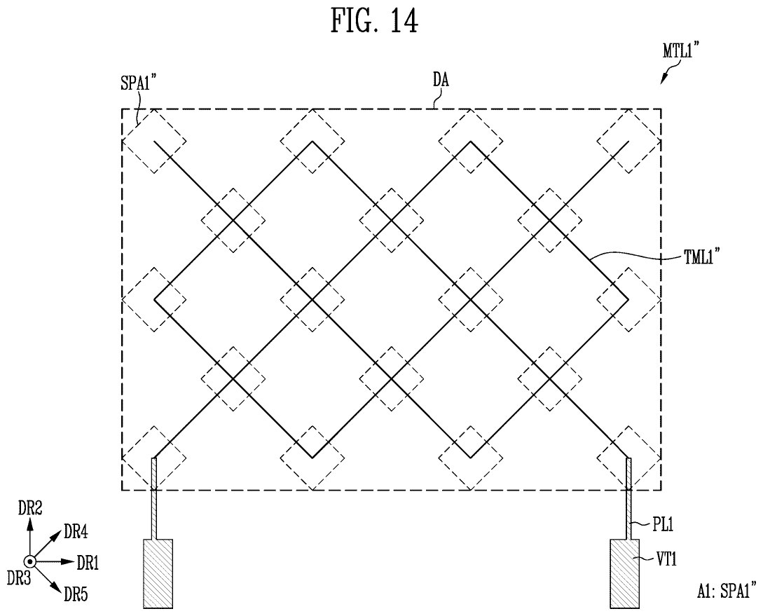

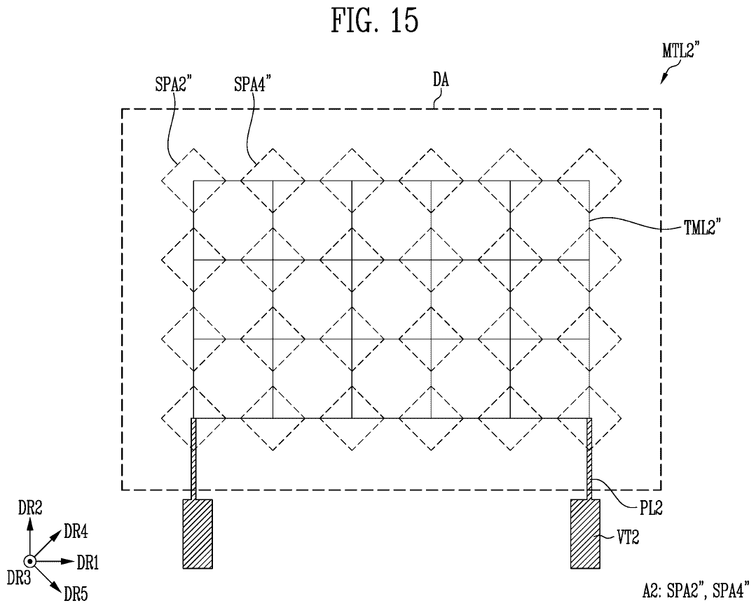

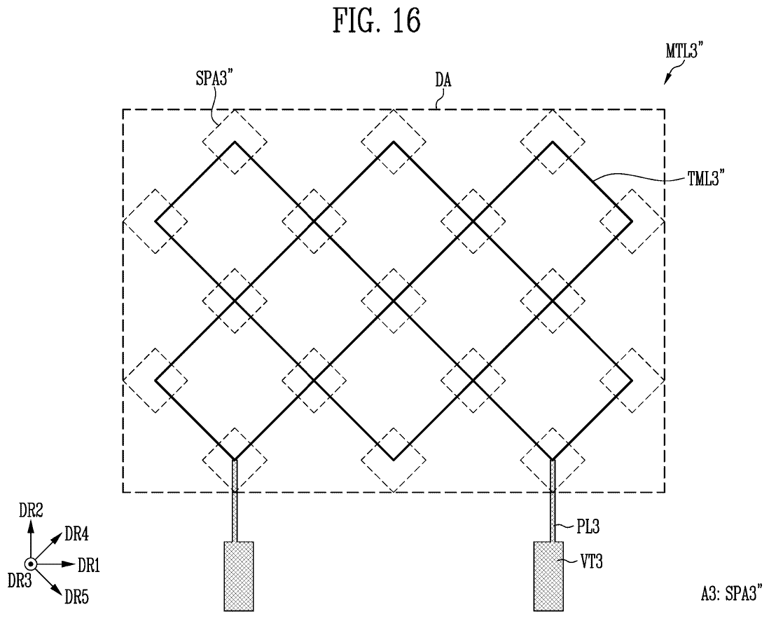

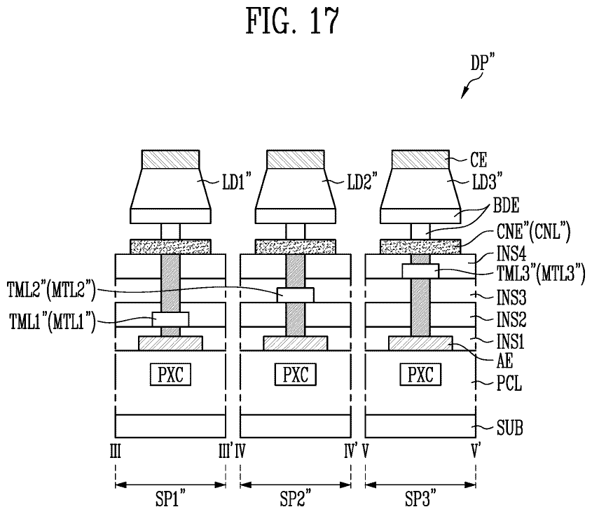

FIG. 12 is a plan view schematically illustrating another embodiment of the display panel of FIG. 3. FIG. 13 is a plan view schematically illustrating the connection layer of FIG. 12. FIG. 14 is a plan view schematically illustrating the first metal layer of FIG. 12. FIG. 15 is a plan view schematically illustrating the second metal layer of FIG. 12. FIG. 16 is a plan view schematically illustrating the third metal layer of FIG. 12.

Referring to FIG. 12, sub-pixels SP″ are included in the display area DA. In one embodiment, the sub-pixels SP″ may be arranged in a Pentile™ structure in a zigzag pattern along a fourth direction DR4 between a first direction DR1 and a second direction DR2 and along a fifth direction DR5 perpendicular to the fourth direction DR4. The sub-pixels SP″ may each be disposed in sub-pixel areas SPA″.

The sub-pixels SP″ may include first to fourth sub-pixels SP1″ to SP4″. The first to fourth sub-pixels SP1″ to SP4″ may form a single pixel PXL. Furthermore, the first to fourth sub-pixels SP1″ to SP4″ may each be disposed in first to fourth sub-pixel areas SPA1″ to SPA4″.

In the display panel DP, the display area DA may include a first area A1, a second area A2, and a third area A3. The first sub-pixel areas SPA1″ may form the first area A1. The second and fourth sub-pixel areas SPA2″ and SPA4″ may form the second area A2. The third sub-pixel areas SPA3″ may form the third area A3.

The first to fourth sub-pixels SP1″ to SP4″ may each include first to fourth light-emitting elements LD1″ to LD4″ that generate and emit light. In other words, first to fourth light-emitting elements LD1″ to LD4″ may each be disposed in the first to fourth sub-pixel areas SPA1″ to SPA4″. Accordingly, first light-emitting elements LD1″ may be disposed in the first area A1, second and fourth light-emitting elements LD2″ and LD4″ may be disposed in the second area A2, and third light-emitting elements LD3″ may be disposed in the third area A3.

The first light-emitting elements LD1″ may overlap the first area A1 and emit light of a first color. The second and fourth light-emitting elements LD2″ and LD4″ may overlap the second area A2 and emit light of a second color different from the first color. The third light-emitting elements LD3″ may overlap the third area A3 and emit light of a third color different from the first and second colors. In an embodiment, the first color may be red, the second color may be green, and the third color may be blue. However, the embodiments are not limited thereto.

Referring further to FIG. 13, the display panel DP may include a connection layer CNL″. The connection layer CNL″ may include connection electrodes CNE″ disposed in the first to fourth sub-pixel areas SPA1″ to SPA4″, respectively. The connection electrodes CNE″ may be spaced apart from each other and electrically connected to the first to fourth light-emitting elements LD1″ to LD4″, respectively. That is, one connection electrode CNE″ may correspond to each sub-pixel SP″. Each of the connection electrodes CNE″ may be electrically connected to one of the first to third transmission lines TML1″ to TML3″, described below.

Referring further to FIG. 14, the display panel DP″ may include a first metal layer MTL1″. The first metal layer MTL1″ may include first transmission lines TML1″ that overlap the first area A1. The first transmission lines TML1″ may be electrically connected to the first light-emitting elements LD1″ disposed in the first area A1. The first transmission lines TML1″ may apply the first voltage to the first light-emitting elements LD1″.

The first transmission lines TML1″ may be electrically connected to the connection electrodes CNE″ disposed in the first area A1. The first transmission lines TML1″ may be electrically connected to the first light-emitting elements LD1″ through the connection electrodes CNE″ disposed in the first area A1. In other words, the connection electrodes CNE″ overlapping the first area A1 may connect the first transmission lines TML1″ with the first light-emitting elements LD1″.

The first transmission lines TML1″ may be interconnected and form a mesh structure to apply the first voltage overall to the first light-emitting elements LD1″ overlapping the first area A1.

The display panel DP may further include a first voltage terminal VT1. The first voltage terminal VT1 may be disposed in the pad area PA. The first voltage terminal VT1 may receive the first voltage and transmit the first voltage to the first transmission lines TML1″. The first power line PL1 may be connected to each of the first voltage terminal VT1 and the first transmission lines TML1″, and transmit the first voltage from the first voltage terminal VT1 to the first transmission lines TML1″.

Referring further to FIG. 15, the display panel DP″ may include a second metal layer MTL2″. The second metal layer MTL2″ may include second transmission lines TML2″ overlapping the second area A2. The second transmission lines TML2″ may be electrically connected to the second and fourth light-emitting elements LD2″ and LD4″ disposed in the second area A2. The second transmission lines TML2″ may apply the second voltage to the second and fourth light-emitting elements LD2″ and LD4″.

The second transmission lines TML2″ may be electrically connected to the connection electrodes CNE″ disposed in the second area A2. The second transmission lines TML2″ may be electrically connected to the second and fourth light-emitting elements LD2″ and LD4″ through the connection electrodes CNE″ disposed in the second area A2. In other words, the connection electrodes CNE″ overlapping the second area A2 may connect the second transmission lines TML2″ with the second and fourth light-emitting elements LD2″ and LD4″.

The second transmission lines TML2″ may be interconnected and form a mesh structure to apply the second voltage overall to the second and fourth light-emitting elements LD2″ and LD4″ overlapping the second area A2.

The second transmission lines TML2″ are insulated from the first transmission lines TML1″, allowing the second voltage to be applied to the second and fourth light-emitting elements LD2″ and LD4″ separately from the first voltage applied to the first light-emitting elements LD1″.

The display panel DP may further include a second voltage terminal VT2. The second voltage terminal VT2 may be disposed in the pad area PA. The second voltage terminal VT2 may receive the second voltage and transmit the second voltage to the second transmission lines TML2″. The second power line PL2 may be connected to each of the second voltage terminal VT2 and the second transmission lines TML2″, and transmit the second voltage from the second voltage terminal VT2 to the second transmission lines TML2″.

Referring further to FIG. 16, the display panel DP″ may include a third metal layer MTL3″. The third metal layer MTL3″ may include third transmission lines TML3″ overlapping the third area A3. The third transmission lines TML3″ may be electrically connected to the third light-emitting elements LD3″ disposed in the third area A3. The third transmission lines TML3″ may apply the third voltage to the third light-emitting elements LD3″.

The third transmission lines TML3″ may be electrically connected to the connection electrodes CNE″ disposed in the third area A3. The third transmission lines TML3″ may be electrically connected to the third light-emitting elements LD3″ through the connection electrodes CNE″ disposed in the third area A3. In other words, the connection electrodes CNE″ overlapping the third area A3 may connect the third transmission lines TML3″ with the third light-emitting elements LD3″.

The third transmission lines TML3″ may be interconnected and form a mesh structure to apply the third voltage overall to the third light-emitting elements LD3″ overlapping the third area A3.

The third transmission lines TML3″ are insulated from the first and second transmission lines TML1″ and TML2″, allowing the third voltage to be applied to the third light-emitting elements LD3″ separately from the first and second voltages applied to the first, second, and fourth light-emitting elements LD1″, LD2″, and LD4″.

The display panel DP″ may further include a third voltage terminal VT3. The third voltage terminal VT3 may be disposed in the pad area PA. The third voltage terminal VT3 may receive the third voltage and transmit the third voltage to the third transmission lines TML3″. The third power line PL3 may be connected to each of the third voltage terminal VT3 and the third transmission lines TML3″, and transmit the third voltage from the third voltage terminal VT3 to the third transmission lines TML3″.

The first voltage may be transmitted only to the first light-emitting elements LD1″ through the first transmission lines TML1″ from the first voltage terminal VT1, the second voltage may be transmitted only to the second and fourth light-emitting elements LD2″ and LD4″ through the second transmission lines TML2″ from the second voltage terminal VT2, and the third voltage may be transmitted only to the third light-emitting elements LD3″ through the third transmission lines TML3″ from the third voltage terminal VT3.

In this case, the third voltage may be greater than the second voltage, and the second voltage may be greater than the first voltage. Specifically, the forward voltage may differ according to the wavelength of the light emitted by each light-emitting element, such that different voltages may be applied to the light-emitting elements according to their forward voltages. The forward voltage of the third light-emitting elements LD3″ for emitting blue light, which has the shortest wavelength, may be the highest, and the forward voltage of the first light-emitting elements LD1″ for emitting red light, which has the longest wavelength, may be the lowest. Accordingly, the third voltage applied to the third light-emitting elements LD3″, which have the highest forward voltage, may be the greatest, and the first voltage applied to the first light-emitting elements LD1″, which have the lowest forward voltage, may be the smallest. The second voltage applied to the second and fourth light-emitting elements LD2″ and LD4″ may be smaller than the third voltage and larger than the first voltage.

The first to third transmission lines TML1″ to TML3″ of the display panel DP″ are structured in multiple layers, allowing voltages to be supplied individually to the light-emitting elements in each layer. That is, the first, second, and third voltages may be individually applied to the first, second, and third light-emitting elements LD1″ to LD3″. This allows different voltages to be applied to different areas within the display area DA.

In one embodiment, by designing separate voltages to be applied to the different areas in the display area DA based on the color of the emitted light, mitigating the voltage drop (IR drop) toward the center of the display area DA, thereby preventing luminance differences from occurring in different areas of the display area DA. Accordingly, the uniformity of the display panel DP″ may be improved and the display quality of the display panel DP″ may be improved.

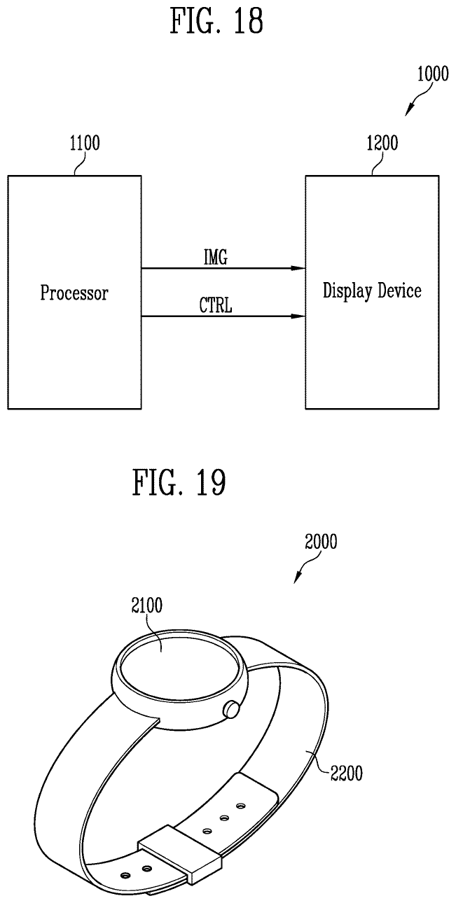

FIG. 17 is a cross-sectional view taken along lines III-III′, IV-IV′, and V-V′ of FIG. 12.

Referring to FIG. 17, a pixel circuit layer PCL may be disposed on the substrate SUB. Anode electrodes AE may be disposed on the pixel circuit layer PCL. The anode electrodes AE may be included in the sub-pixels SP″, respectively and connected to corresponding circuit elements PXC, respectively.

Each of the anode electrodes AE may be electrically connected to one of the first, second, or third transmission lines TML1″ to TML3″. Through the first, second, or third transmission lines TML1″ to TML3″, each anode electrode AE may receive the first, second, or third voltage.

A first insulating layer INS1 may be disposed on the pixel circuit layer PCL. The first insulating layer INS1 may cover the anode electrodes AE on the anode electrodes AE.

A first metal layer MTL1″ may be disposed on the first insulating layer INS1. The first metal layer MTL1″ may include the first transmission line TML1″ and may receive the first voltage. The first transmission line TML1″ may overlap the first sub-pixel SP1″ and may be electrically connected to the anode electrode AE of the first sub-pixel SP1″ through a contact hole penetrating the first insulating layer INS1. In other words, each of the first transmission lines TML1″ may transmit the first voltage to some of the light-emitting elements LD″, for example, the first light-emitting elements LD1″ through the connection electrodes CNE″.

A second insulating layer INS2 may be disposed on the first insulating layer INS1. The second insulating layer INS2 may cover the first metal layer MTL1″ on the first metal layer MTL1″.

A second metal layer MTL2″ may be disposed on the second insulating layer INS2. The second metal layer MTL2″ may be insulated from the first metal layer MTL1″. The second metal layer MTL2″ may include the second transmission line TML2″ and may receive the second voltage, applied separately from the first voltage. The second transmission line TML2″ may overlap the second sub-pixel SP2″ and may be electrically connected to the anode electrode AE of the second sub-pixel SP2″ through contact holes penetrating both the first insulating layer INS1 and the second insulating layer INS2. In other words, each of the second transmission lines TML2″ may transmit the second voltage to some of the light-emitting elements LD″, excluding the first light-emitting elements LD1″, for example, to the second light-emitting elements LD2″ through the connection electrodes CNE″.

A third insulating layer INS3 may be disposed on the second insulating layer INS2. The third insulating layer INS3 may cover the second metal layer MTL2″ on the second metal layer MTL2″.

A third metal layer MTL3″ may be disposed on the third insulating layer INS3. The third metal layer MTL3″ may be insulated from the first metal layer MTL1″ and the second metal layer MTL2″. The third metal layer MTL3″ may include the third transmission line TML3″ and may receive the third voltage, applied separately from the first and second voltages. The third transmission line TML3″ may overlap the third sub-pixel SP3″ and may be electrically connected to the anode electrode AE of the third sub-pixel SP3″ through contact holes penetrating the first to third insulating layers INS1˜INS3. In other words, each of the third transmission lines TML3″ may transmit the third voltage to the remaining light-emitting elements LD″, excluding the first and second light-emitting elements LD1″ and LD2″, for example, to the third light-emitting elements LD3″ through the connection electrodes CNE″.

Although FIG. 17 describes the first to third metal layers MTL1″ to MTL3″ as being sequentially disposed, this is exemplary, and in some embodiments, the stacking order of the first to third metal layers MTL1″ to MTL3″ may vary.

A fourth insulating layer INS4 may be disposed on the third insulating layer INS3. The fourth insulating layer INS4 may cover the third metal layer MTL3″ on the third metal layer MTL3″.

A connection layer CNL″ may be disposed on the fourth insulating layer INS4. The connection layer CNL″ may be individually connected to the first to third metal layers MTL1″ to MTL3″. The connection layer CNL″ may include spaced-apart connection electrodes CNE″. The connection electrodes CNE″ may each overlap the first to third sub-pixels SP1″ to SP3″. Each of connection electrodes CNE″ may be electrically connected to one of the first to third transmission lines TML1″ to TML3″.

Bonding electrodes BDE may be disposed on the connection layer CNL″. The first to third light-emitting elements LD1″ to LD3″ may be disposed on the bonding electrodes BDE. The first to third light-emitting elements LD1″ to LD3″ may each be included in the first to third sub-pixels SP1″ to SP3′″ and may each be electrically connected to the connection electrodes CNE″ of the connection layer CNL″ through the bonding electrodes BDE.

Cathode electrodes CE may each be disposed on the light-emitting elements LD″. The cathode electrodes CE may be directly connected to the light-emitting elements LD″. In this case, the cathode electrodes CE may serve as common electrodes and may be electrically connected to each other.

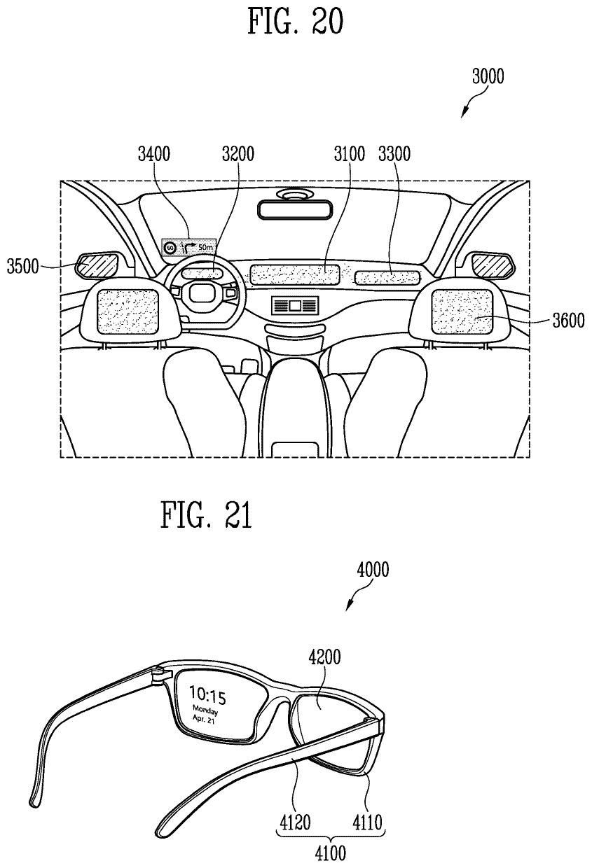

FIG. 18 is a block diagram illustrating an embodiment of a display system.

Referring to FIG. 18, the display system 1000 may include a processor 1100 and a display device 1200.

The processor 1100 may perform various tasks and computations. In some embodiments, the processor 1100 may include an application processor, a graphic processor, a microprocessor, a central processing unit (CPU), or the like. The processor 1100 may be connected to and control other components of the display system 1000 through a bus system.

The processor 1100 may transmit image data IMG and control signals CTRL to the display device 1200. The display device 1200 may display an image based on the image data IMG and control signals CTRL. The display device 1200 may be configured similarly to the display device DD described with reference to FIG. 1. In such a case, the image data IMG and control signals CTRL may be provided as the input image data IMG and control signals CTRL in FIG. 1, respectively.

The display system 1000 may include a computing system that provides an image display function, such as a smart watch, mobile phone, smart phone, portable computer, tablet personal computer, watch phone, automotive display, smart glasses, portable multimedia player (PMP), navigation system, or ultra mobile personal computer (UMPC). Additionally, the display system 1000 may include at least one of a head-mounted display (HMD), virtual reality (VR) device, mixed reality (MR) device, or augmented reality (AR) device.

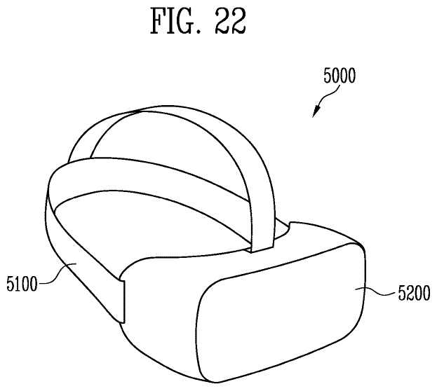

FIGS. 19 to 22 are perspective views illustrating application examples of the display system of FIG. 18.

Referring to FIG. 19, the display system 1000 of FIG. 18 may be applied to a smart watch 2000 that includes a display 2100 and a strap 2200.

The smart watch 2000 may be a wearable electronic device. For example, the smart watch 2000 may have a structure in which the strap 2200 is mounted on a user's wrist. Here, the display system 1000 and/or the display device 1200 may be applied to the display 2100, providing image data including time information to the user.

Referring to FIG. 20, the display system 1000 of FIG. 18 may be applied to an automotive display system 3000. Here, the automotive display system 3000 may include a computing system that provides image data, equipped inside and/or outside a vehicle.

For example, the display system 1000 and/or the display device 1200 may be applied to at least one of an infotainment panel 3100, cluster 3200, co-driver display 3300, head-up display 3400, side mirror display 3500, and rear seat display 3600 provided in a vehicle.

Referring to FIG. 21, the display system 1000 of FIG. 18 may be applied to smart glasses 4000. The smart glasses 4000 may be a wearable electronic device that can be worn on a user's head. For example, the smart glasses 4000 may be a wearable device for augmented reality.

The smart glasses 4000 may include a frame 4100 and a lens part 4200. The frame 4100 may include a housing 4110 that supports the lens part 4200 and a temple 4120 for the user's wear. The temple 4120 may be connected to the housing 4110 via a hinge, allowing it to fold or unfold relative to the housing 4110.

The frame 4100 may include a battery, touch pad, microphone, camera, and the like. Additionally, the frame 4100 may include a projector that outputs light, a processor that controls optical signals, and the like.

The lens part 4200 may include optical components that transmit or reflect light. For example, the lens part 4200 may include glass, transparent synthetic resin, and the like.

The lens part 4200 may reflect an image, created by an optical signal emitted from the projector of the frame 4100, onto the rear surface of the lens part 4200 (e.g., the surface facing the user's eyes), allowing the user's eyes to recognize visual information. For example, the user may recognize visual information such as the time and date displayed on the lens part 4200. In this case, the projector and/or the lens part 4200 may serve as a type of display device. The display device 1200 may be applied to the projector and/or the lens part 4200.

Referring to FIG. 22, the display system 1000 of FIG. 18 may be applied to a head-mounted display device 5000.

The head-mounted display device 5000 may be a wearable electronic device that can be worn on the user's head. For example, the head-mounted display device 5000 may be a wearable device for virtual reality or mixed reality.

The head-mounted display device 5000 may include a head-mounting band 5100 and a display device housing 5200. The head-mounting band 5100 may be connected to the display device housing 5200. The head-mounting band 5100 may include horizontal and/or vertical bands to secure the head-mounted display device 5000 to the user's head. The horizontal band may surround the side of the user's head, and the vertical band may surround the top of the user's head. However, the embodiments are not limited to this. For example, the head-mounting band 5100 may be implemented in the form of eyeglass frames, a helmet, or other shapes.

The display device housing 5200 may accommodate the display system 1000 and/or the display device 1200.

The technical spirit of the present invention has been specifically described with reference to the aforementioned embodiments, but it should be noted that these embodiments are merely for explanatory purposes and are not intended to limit the invention. Those skilled in the art will appreciate that various modifications are possible within the scope of the technical spirit of the present invention.

The scope of the present invention should not be limited to the details described in the detailed description but should be defined by the claims. Any changes or modifications derived from the meaning and scope of the claims and their equivalents should be construed as being included within the scope of the present invention.

What is claimed is:

1. A display device comprising:
a substrate including a first area and a second area not overlapping the first area;
a plurality of light-emitting elements disposed on the substrate and which emit light;
first transmission lines, which apply a first voltage to light-emitting elements overlapping with the first area among the plurality of light-emitting elements;
second transmission lines insulated from the first transmission lines, and which apply a second voltage to light-emitting elements overlapping with the second area among the plurality of light-emitting elements; and
a connection layer connecting each of the first and second transmission lines to each of the plurality of light-emitting elements.

2. The display device of claim 1, wherein the first area is located at a central portion of the substrate, and the second area surrounds the first area.

3. The display device of claim 1, wherein:
the first transmission lines are interconnected to form a first mesh structure, and
the second transmission lines are interconnected to form a second mesh structure.

4. The display device of claim 1, further comprising:
a first voltage terminal configured to receive the first voltage and transmit the first voltage to the first transmission lines; and
a second voltage terminal configured to receive the second voltage and transmit the second voltage to the second transmission lines.

5. The display device of claim 1, wherein the connection layer includes a plurality of connection electrodes spaced apart from each other.

6. The display device of claim 5, wherein the plurality of connection electrodes are electrically connected to the plurality of light-emitting elements, respectively.

7. The display device of claim 6, wherein each of the plurality of connection electrodes is electrically connected to one of the first transmission lines and the second transmission lines.

8. The display device of claim 5, wherein the substrate further comprises a third area not overlapping the first and second areas.

9. The display device of claim 8, wherein the plurality of light-emitting elements include:
first light-emitting elements, which emit light of a first color, and overlaps with the first area;
second light-emitting elements, which emit light of a second color different from the first color, and overlaps with the second area; and
third light-emitting elements, which emit light of a third color different from the first and second colors, and overlapping with the third area.

10. The display device of claim 9, further comprising:
third transmission lines insulated from the first and second transmission lines, and which apply a third voltage to the third light-emitting elements among the plurality of light-emitting elements.

11. The display device of claim 10, wherein the first color is red, the second color is green, the third color is blue, the third voltage is greater than each of the first and second voltages, and the second voltage is greater than the first voltage.

12. The display device of claim 10, wherein each of the plurality of connection electrodes is electrically connected to one of the first transmission lines, the second transmission lines, and the third transmission lines.

13. The display device of claim 10, further comprising:
a third voltage terminal configured to receive the third voltage and transmit the third voltage to the third transmission lines.

14. A display device comprising:
a substrate;
a pixel circuit layer disposed on the substrate;
a first insulating layer disposed on the pixel circuit layer;
a first metal layer disposed on the first insulating layer, and which receives a first voltage;
a second insulating layer disposed on the first metal layer;
a second metal layer disposed on the second insulating layer, insulated from the first metal layer, and which receives a second voltage separately applied from the first voltage;
a third insulating layer disposed on the second metal layer;
a connection layer disposed on the third insulating layer, and electrically connected to each of the first and second metal layers; and
light-emitting elements disposed on the connection layer, and electrically connected to the connection layer.

15. The display device of claim 14, wherein:
the first metal layer includes first transmission lines, which are interconnected, and
the second metal layer includes second transmission lines, which are interconnected.

16. The display device of claim 15, wherein the connection layer includes a plurality of connection electrodes spaced apart from each other, and each electrically connected to one of the first transmission lines and the second transmission lines.

17. The display device of claim 16, wherein:
the first transmission lines are configured to transmit the first voltage to some of the light-emitting elements through the connection electrodes, respectively, and
the second transmission lines are configured to transmit the second voltage to the remaining of the light-emitting elements through the connection electrodes, respectively.

18. The display device of claim 16, further comprising:
anode electrodes disposed between the pixel circuit layer and the first insulating layer,
wherein each of the anode electrodes is electrically connected to one of the first transmission lines and the second transmission lines.

19. A display device comprising:
a substrate;
a pixel circuit layer disposed on the substrate;
light-emitting elements disposed on the pixel circuit layer;
a connection layer disposed on the light-emitting elements, and electrically connected to the light-emitting elements;
a first insulating layer disposed on the connection layer;
a first metal layer disposed on the first insulating layer, electrically connected to the connection layer, and which receives a first voltage;
a second insulating layer disposed on the first metal layer; and
a second metal layer disposed on the second insulating layer, electrically connected to the connection layer, insulated from the first metal layer, and which receives a second voltage separately applied from the first voltage.

20. The display device of claim 19, further comprising:
cathode electrodes disposed on the second metal layer,
wherein each of the cathode electrodes is electrically connected to one of the first metal layer and the second metal layer.

21. An electronic device comprising:
a display device; and
a power supply configured to provide power to the display device,
wherein the display device comprises:
a substrate including a first area and a second area not overlapping the first area;
a plurality of light-emitting elements disposed on the substrate and which emit light;
first transmission lines, which apply a first voltage to light-emitting elements overlapping with the first area among the plurality of light-emitting elements;
second transmission lines insulated from the first transmission lines, and which apply a second voltage to light-emitting elements overlapping with the second area among the plurality of light-emitting elements; and
a connection layer connecting each of the first and second transmission lines to each of the plurality of light-emitting elements.
